(19) United States
(12) Patent Application Publication
(10) Pub. No.: US 2026/0213773 A1
(43) Pub. Date: Jul. 23, 2026

(54) HARD ERROR CORRECTION BASED ON SELECTIVE ERROR COUNTS IN LOW-DENSITY PARITY CHECK CODES IN MEMORY DEVICES

(71) Applicant: SK hynix Inc., Icheon-si (KR)

(72) Inventors: Pengfei Huang, San Jose, CA (US); Fan Zhang, Fremont, CA (US)

(21) Appl. No.: 19/028,309

(22) Filed: Jan. 17, 2025

(51) Int. Cl. H03M 13/39; H03M 13/11

(52) U.S. Cl. CPC H03M 13/3927; H03M 13/1148

(57) ABSTRACT

Methods and systems for improving performance of an iterative decoder in a non-volatile memory are described. In an example method, the performance of the iterative decoder, which is configured to use (M−1) soft read channels, M bins, and K bits per log-likelihood ratio (LLR) value, is improved based on (a) initializing the LLR values of hard error bins of the M bins such that a magnitude of the LLR for the first bin and the last bin of the M bins is less than 2^{K-1}−1, and (b) adapting those LLR values during the decoding process based on selectively counting hard errors upon determining that a condition, indicative of the iterative decoder not being complete, is satisfied. The improved decoder exhibits better soft decoding correction capabilities in both waterfall and error floor regions. An example system includes one or more processors configured to implemented the above-described method.

### TECHNICAL FIELD

This patent document generally relates to non-volatile memory devices, and more specifically, to low-density parity-check (LDPC) codes used in non-volatile memory devices.

### BACKGROUND

Data integrity is a critical feature for any data storage device and data transmission. Bit errors, which occur when individual bits of data are incorrectly altered during storage or transmission, can significantly compromise data integrity in solid state memory storage (e.g., NAND flash) devices. These errors can result from various factors such as electrical interference, wear and tear of memory cells, or manufacturing defects. When bit errors occur, the data read from the solid state drive (SSD) may not match the data originally written, leading to corrupted files, application errors, and potential data loss. To mitigate the impact of bit errors, SSDs employ error detection and correction mechanisms like error correction codes (ECCs), which can identify and correct a certain number of bit errors. However, if the number of errors exceeds the correction capability of the ECCs, data integrity is compromised, underscoring the importance of robust error management strategies in maintaining the reliability and accuracy of stored data.

### SUMMARY

Embodiments of the disclosed technology relate to methods and systems that improve performance of an iterative low-density parity check (LDPC) decoder in a memory device. In an example, the performance of the decoder in the memory device is improved by initializing the log-likelihood ratio (LLR) values of hard error bins, and then adapting those LLR values during the decoding process based on selectively counting hard errors. The improved decoder exhibits better soft decoding correction capabilities in both waterfall and error floor regions.

In an example aspect, a method for improving performance of an iterative decoder in a non-volatile memory is described. The method includes (a) determining a bin label sequence by reading, from at least one cell of the memory device, a noisy codeword using N soft-read channels that divide a voltage range associated with the at least one cell into M bins. In this example, a bin label of the bin label sequence is an index of a bin of the M bins that corresponds to reading a respective bit of the noisy codeword using the N soft-read channels, and where N and M=N+1 are positive integers. The method further includes (b) initializing a log-likelihood ratio (LLR) vector for each of the M bins, (c) generating an LLR sequence by applying the LLR vector to the bin label sequence, and (d) performing a decoding iteration on the LLR sequence to generate a decoded data sequence. In this example, each LLR of the LLR vector is represented using K bits, a magnitude of an LLR for a first bin of the M bins and a last bin of the M bins is less than 2^{K-1}−1, and K is a positive integer. The method then includes, upon determining that a condition, indicative of the noisy codeword not being successfully decoded, is satisfied, (e) counting hard errors in the decoded data sequence by incrementing at least one of multiple counters based on comparing corresponding elements of the decoded data sequence and the bin label sequence, and (f) updating the LLR sequence by recalculating, based on the multiple counters, the LLR for the first bin and the LLR for the last bin. The method finally includes repeating operations (d) through (f) until the noisy codeword is successfully decoded or an index of the decoding iteration has exceeded a maximum number of decoding iterations. In some examples, the condition being satisfied includes a checksum of the decoded data sequence being less than a first threshold.

In another example aspect, the method may be embodied in the form of an apparatus that includes a processor and a memory coupled to the processor.

In yet another example aspect, the method may be embodied in the form of processor-executable instructions and stored on a computer-readable program medium.

The subject matter described in this patent document can be implemented in specific ways that provide one or more of the following features.

### BRIEF DESCRIPTION OF THE DRAWINGS

FIG. 1 illustrates an example of a memory system.

FIG. 2 is an illustration of an example non-volatile memory device.

FIG. 3 is an example diagram illustrating the cell voltage level distribution (Vₜₕ) of a non-volatile memory device.

FIG. 4 is another example diagram illustrating the cell voltage level distribution (Vₜₕ) of a non-volatile memory device.

FIG. 5 is an example diagram illustrating the cell voltage level distribution (Vₜₕ) of a non-volatile memory device before and after program interference.

FIG. 6 is an example diagram illustrating the cell voltage level distribution (Vₜₕ) of a non-volatile memory device as a function of the reference voltage.

FIG. 7 is an example diagram illustrating the seven soft read channels of a single-level cell (SLC) NAND.

FIG. 8 illustrates an example of gray labeling for a triple-level cell (TLC) NAND.

FIG. 9 is an example diagram illustrating the soft read channels of the TLC NAND.

FIG. 10 is an example plot illustrating a soft correction loss in the waterfall region due to mismatches in small log-likelihood ratios (LLRs) in the hard error bins.

FIG. 11 is an example plot illustrating a soft correction loss in both the waterfall region and the error floor region due to mismatches in large LLRs in the hard error bins.

FIG. 12 is a block diagram illustrating an example architecture for improving soft decoding in a memory device based on selective error counts.

FIG. 13 illustrates a flowchart of an example method for improving the performance of an iterative decoder in a memory device.

FIG. 14 is an example diagram illustrating a storage device that can be configured to implement the described embodiments.

### DETAILED DESCRIPTION

Semiconductor memory devices may be volatile or nonvolatile. The volatile semiconductor memory devices perform read and write operations at high speeds, while contents stored therein may be lost at power-off. The nonvolatile semiconductor memory devices may retain contents stored therein even at power-off. The nonvolatile semiconductor memory devices may be used to store contents, which must be retained regardless of whether they are powered.

With an increase in a need for a large-capacity memory device, a multi-level cell (MLC) or multi-bit memory device storing multi-bit data per cell is becoming more common. However, memory cells in an MLC non-volatile memory device must have threshold voltages corresponding to four or more discriminable data states in a limited voltage window. For improvement of data integrity in non-volatile memory devices, the levels, and distributions of read voltages for discriminating the data states must be adjusted over the lifetime of the memory device to have optimal values during read operations and/or read attempts.

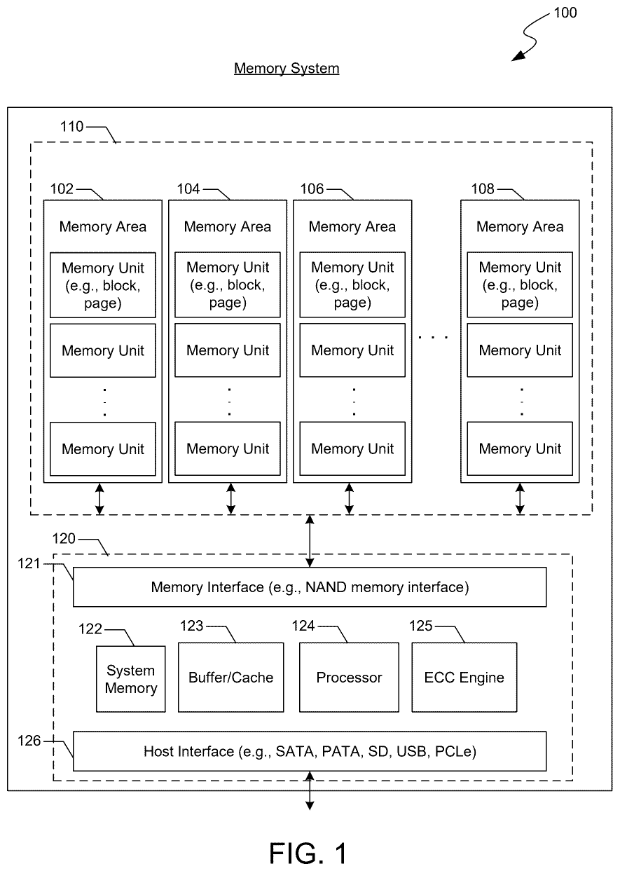

FIGS. 1-6 overview a non-volatile memory system (e.g., a flash-based memory, NAND flash) in which embodiments of the disclosed technology may be implemented.

FIG. 1 is a block diagram of an example of a memory system 100 implemented based on some embodiments of the disclosed technology. The memory system 100 includes a memory module 110 that can be used to store information for use by other electronic devices or systems. The memory system 100 can be incorporated (e.g., located on a circuit board) in other electronic devices and systems. Alternatively, the memory system 100 can be implemented as an external storage device such as a USB flash drive and a solid-state drive (SSD).

The memory module 110 included in the memory system 100 can include memory areas (e.g., memory arrays) 102, 104, 106, and 108. Each of the memory areas 102, 104, 106, and 108 can be included in a single memory die or in multiple memory dice. The memory die can be included in an integrated circuit (IC) chip.

Each of the memory areas 102, 104, 106, and 108 includes a plurality of memory cells. Read, program, or erase operations can be performed on a memory unit basis. Thus, each memory unit can include a predetermined number of memory cells. The memory cells in a memory area 102, 104, 106, and 108 can be included in a single memory die or in multiple memory dice.

The memory cells in each of memory areas 102, 104, 106, and 108 can be arranged in rows and columns in the memory units. Each of the memory units can be a physical unit. For example, a group of a plurality of memory cells can form a memory unit. Each of the memory units can also be a logical unit. For example, the memory unit can be a block or a page that can be identified by a unique address such as a block address or a page address, respectively. For another example, wherein the memory areas 102, 104, 106, and 108 can include computer memories that include memory banks as a logical unit of data storage, the memory unit can be a bank that can be identified by a bank address. During a read or write operation, the unique address associated with a particular memory unit can be used to access that particular memory unit. Based on the unique address, information can be written to or retrieved from one or more memory cells in that particular memory unit.

The memory cells in the memory areas 102, 104, 106, and 108 can include non-volatile memory cells. Examples of non-volatile memory cells include flash memory cells, phase change random-access memory (PRAM) cells, magnetoresistive random-access memory (MRAM) cells, or other types of non-volatile memory cells. In an example implementation where the memory cells are configured as NAND flash memory cells, the read or write operation can be performed on a page basis. However, an erase operation in a NAND flash memory is performed on a block basis.

Each of the non-volatile memory cells can be configured as a single-level cell (SLC) or multiple-level memory cell. A single-level cell can store one bit of information per cell. A multiple-level memory cell can store more than one bit of information per cell. For example, each of the memory cells in the memory areas 102, 104, 106, and 108 can be configured as a multi-level cell (MLC) to store two bits of information per cell, a triple-level cell (TLC) to store three bits of information per cell, or a quad-level cells (QLC) to store four bits of information per cell. In another example, each of the memory cells in memory area 102, 104, 106, and 108 can be configured to store at least one bit of information (e.g., one bit of information or multiple bits of information), and each of the memory cells in memory area 102, 104, 106, and 108 can be configured to store more than one bit of information.

As shown in FIG. 1, the memory system 100 includes a controller module 120. The controller module 120 includes a memory interface 121 to communicate with the memory module 110, a host interface 126 to communicate with a host (not shown), a processor 124 to execute firmware-level code, and caches and memories 123 and 122, respectively to temporarily or persistently store executable firmware/instructions and associated information. In some implementations, the controller unit 120 can include an error correction engine 125 to perform error correction operation on information stored in the memory module 110. Error correction engine 125 can be configured to detect/correct single bit error or multiple bit errors. In another implementation, error correction engine 125 can be located in the memory module 110.

The host can be a device or a system that includes one or more processors that operate to retrieve data from the memory system 100 or store or write data into the memory system 100. In some implementations, examples of the host can include a personal computer (PC), a portable digital device, a digital camera, a digital multimedia player, a television, and a wireless communication device.

In some implementations, the controller module 120 can also include a host interface 126 to communicate with the host. Host interface 126 can include components that comply with at least one of host interface specifications, including but not limited to, Serial Advanced Technology Attachment (SATA), Serial Attached Small Computer System Interface (SAS) specification, Peripheral Component Interconnect Express (PCIe).

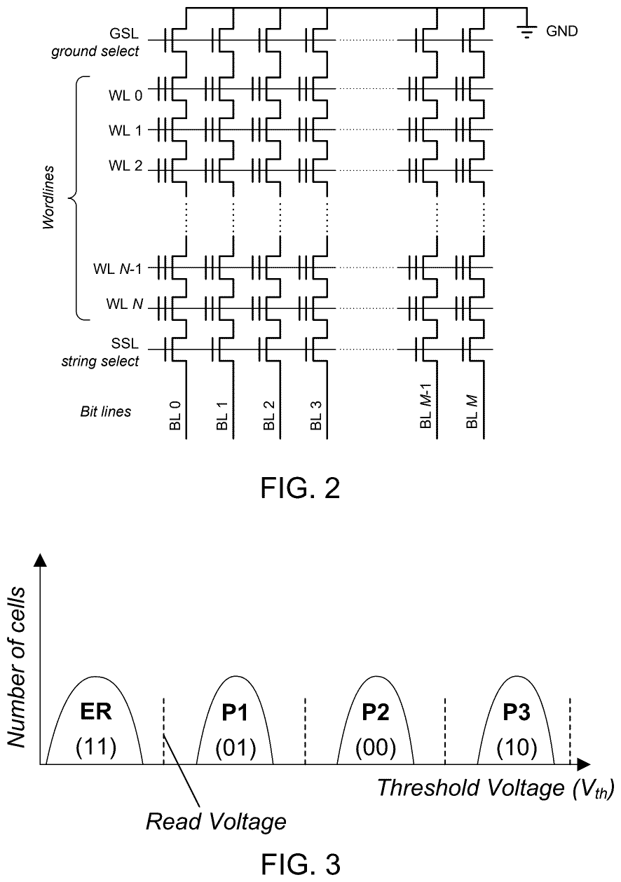

FIG. 2 illustrates an example of a memory cell array implemented based on some embodiments of the disclosed technology.

In some implementations, the memory cell array can include NAND flash memory array that is partitioned into many blocks, and each block contains a certain number of pages. Each block includes a plurality of memory cell strings, and each memory cell string includes a plurality of memory cells.

In some implementations where the memory cell array is NAND flash memory array, read and write (program) operations are performed on a page basis, and erase operations are performed on a block basis. All the memory cells within the same block must be erased at the same time before performing a program operation on any page included in the block. In an implementation, NAND flash memories may use an even/odd bit-line structure. In another implementation, NAND flash memories may use an all-bit-line structure. In the even/odd bit-line structure, even and odd bit-lines are interleaved along each word-line and are alternatively accessed so that each pair of even and odd bit-lines can share peripheral circuits such as page buffers. In all-bit-line structure, all the bit-lines are accessed at the same time.

FIG. 3 illustrates an example of threshold voltage distribution curves in a multi-level cell device, wherein the number of cells for each program/erase state is plotted as a function of the threshold voltage. As illustrated therein, the threshold voltage distribution curves include the erase state (denoted “ER” and corresponding to “11”) with the lowest threshold voltage, and three program states (denoted “P1”, “P2” and “P3” corresponding to “01”, “00” and “10”, respectively) with read voltages in between the states (denoted by the dotted lines). In some embodiments, each of the threshold voltage distributions of program/erase states has a finite width because of differences in material properties across the memory array.

Although FIG. 3 shows a multi-level cell device by way of example, each of the memory cells can be configured to store any number of bits per cell. In some implementations, each of the memory cells can be configured as a single-level cell (SLC) to store one bit of information per cell, or as a triple-level cell (TLC) to store three bits of information per cell, or as a quad-level cells (QLC) to store four bits of information per cell.

In writing more than one data bit in a memory cell, fine placement of the threshold voltage levels of memory cells is needed because of the reduced distance between adjacent distributions. This is achieved by using incremental step pulse program (ISPP), i.e., memory cells on the same word-line are repeatedly programmed using a program-and-verify approach with a staircase program voltage applied to word-lines. Each programmed state associates with a verify voltage that is used in verify operations and sets the target position of each threshold voltage distribution window.

Read errors can be caused by distorted or overlapped threshold voltage distribution. An ideal memory cell threshold voltage distribution can be significantly distorted or overlapped due to, e.g., program and erase (P/E) cycle, cell-to-cell interference, and data retention errors, which will be discussed in the following, and such read errors may be managed in most situations by using error correction codes (ECCO).

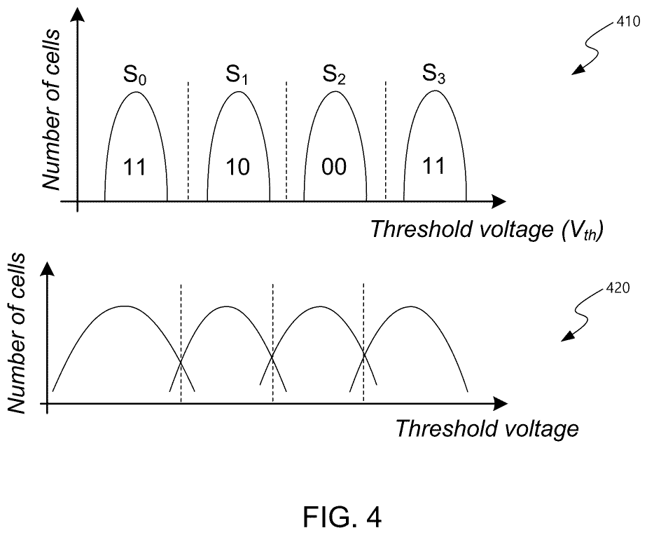

FIG. 4 illustrates an example of ideal threshold voltage distribution curves 410 and an example of distorted threshold voltage distribution curves 420. The vertical axis indicates the number of memory cells that has a particular threshold voltage represented on the horizontal axis.

For n-bit multi-level cell NAND flash memory, the threshold voltage of each cell can be programmed to 2ⁿ possible values. In an ideal multi-level cell NAND flash memory, each value corresponds to a non-overlapping threshold voltage window.

Flash memory P/E cycling causes damage to a tunnel oxide of floating gate of a charge trapping layer of cell transistors, which results in threshold voltage shift and thus gradually degrades memory device noise margin. As P/E cycles increase, the margin between neighboring distributions of different programmed states decreases and eventually the distributions start overlapping. The data bit stored in a memory cell with a threshold voltage programmed in the overlapping range of the neighboring distributions may be misjudged as a value other than the original targeted value.

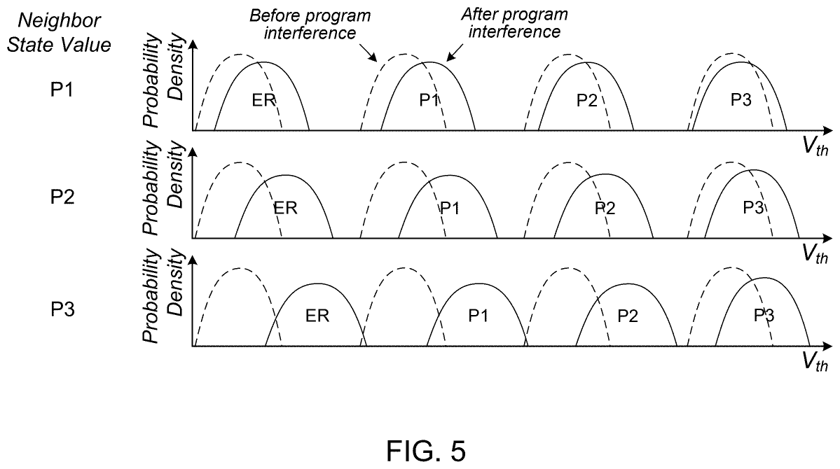

FIG. 5 illustrates an example of a cell-to-cell interference in NAND flash memory. The cell-to-cell interference can also cause threshold voltages of flash cells to be distorted. The threshold voltage shift of one memory cell transistor can influence the threshold voltage of its adjacent memory cell transistor through parasitic capacitance-coupling effect between the interfering cell and the victim cell. The amount of the cell-to-cell interference may be affected by NAND flash memory bit-line structure. In the even/odd bit-line structure, memory cells on one word-line are alternatively connected to even and odd bit-lines and even cells are programmed ahead of odd cells in the same word-line. Therefore, even cells and odd cells experience different amount of cell-to-cell interference. Cells in all-bit-line structure suffer less cell-to-cell interference than even cells in the even/odd bit-line structure, and the all-bit-line structure can effectively support high-speed current sensing to improve the memory read and verify speed.

The dotted lines in FIG. 5 denote the nominal distributions of P/E states (before program interference) of the cells under consideration, and the “neighbor state value” denotes the value that the neighboring state has been programmed to. As illustrated in FIG. 5, if the neighboring state is programmed to P1, the threshold voltage distributions of the cells under consideration shift by a specific amount. However, if the neighboring state is programmed to P2, which has a higher threshold voltage than P1, that results in a greater shift compared to the neighboring state being P1. Similarly, the shift in the threshold voltage distributions is greatest when the neighboring state is programmed to P3.

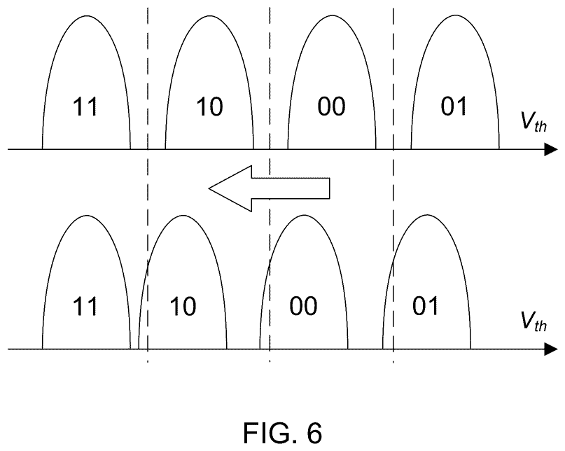

FIG. 6 illustrates an example of a retention error in NAND flash memory by comparing normal threshold-voltage distribution and shifted threshold-voltage distribution. The data stored in NAND flash memories tend to get corrupted over time and this is known as a data retention error. Retention errors are caused by loss of charge stored in the floating gate or charge trap layer of the cell transistor. Due to wear of the floating gate or charge trap layer, memory cells with more program erase cycles are more likely to experience retention errors. In the example of FIG. 6, comparing the top row of voltage distributions (before corruption) and the bottom row of distributions (contaminated by retention error) reveals a shift to the left.

In the NAND flash memory examples described above, a “hard read” is an operation to determine hard information such as by comparing the threshold voltage of a memory cell, e.g., flash memory cell, to reference voltages delineating ranges of voltages corresponding to particular states. A hard read can be full-confidence sensing, e.g., sensing that does not involve other information about the digits of the data value such as confidence. That is, the data value sensed from the memory cell is assumed to be the data value that was programmed to the memory. For full-confidence sensing, a digit of a data value that is sensed, e.g., read from memory, as a “0” will have a corresponding LLR of +1, and a data value that is sensed as a “1” can have a corresponding LLR of −1.

Furthermore, the example NAND-based storage systems discussed above use low-density parity check (LDPC) codes, which are a type of error-correcting code used to ensure data integrity in non-volatile memory (NVM) devices, such as flash memory. The encoding process begins by dividing the original data into blocks of a fixed size. A sparse parity-check matrix is then used to generate parity bits, which are combined with the data bits to form a codeword. This codeword is stored in the non-volatile memory, which retains data even when power is lost.

When data is read from the non-volatile memory, it may contain errors due to various factors like wear and tear of the memory cells or environmental conditions. LDPC codes detect and correct these errors through a process that involves calculating a syndrome by multiplying the read codeword by the transpose of the parity-check matrix (typically denoted H). If the syndrome is non-zero, it indicates the presence of errors. An iterative decoding algorithm (e.g., the belief propagation algorithm) is then used to correct the errors. This algorithm iteratively updates probabilities of each bit being 0 or 1 by passing messages between variable nodes and check nodes in a bipartite graph until the probabilities converge to stable values, resulting in the corrected codeword and the extraction of the original data.

In NAND-based storage systems (e.g., the examples illustrated in FIGS. 1-6) and solid-state drive (SSD) applications, hard errors have a significant impact on the LDPC soft decoding correction capability in the memory device. Hard errors from the NAND flash memory channel are defined as erroneous bits with wrong sign and maximal magnitude. It is observed that when a mismatched log-likelihood ratio (LLR) for the hard error bits is used, LDPC soft decoding correction capability is significantly degraded. When a lower magnitude LLR is used on bits that fall in the hard error bins, a loss in the correction capability in the waterfall region is observed. When a higher magnitude LLR is used on those bits that fall in the hard error bins, the correction capability loss is observed in both the waterfall region and the error floor region.

In the example of LDPC codes, the waterfall region is characterized by a steep decline in the bit error rate (BER) as the signal-to-noise ratio (SNR) increases. This region is named for its appearance on a BER vs. SNR plot, where the curve drops sharply, resembling a waterfall. In this region, the LDPC decoder effectively corrects most errors, and the performance improves rapidly with increasing SNR. The error floor region typically occurs at higher SNR values, where the BER curve flattens out and decreases more slowly compared to the waterfall region. In this region, the error rate does not improve significantly with further increases in SNR. The error floor is caused by the presence of certain error patterns, known as trapping sets or stopping sets, that the LDPC decoder struggles to correct. These patterns are typically rare but can lead to persistent errors that are difficult to eliminate, even with high SNR.

Embodiments of the disclosed technology provide methods and systems directed to initializing the LLRs of received bits in hard error bins, as well as updating these the LLRs of hard error bins during the soft decoding process, by selectively counting hard errors. The described embodiments are configured to adjust mismatched LLRs progressively such that they converge to the optimal LLR values when there are either a large number of hard errors or a small number of hard errors. The disclosed technology advantageously improves the LDPC soft decoding correction capability in both the waterfall and the error floor regions.

In some embodiments, and for an LDPC code with m×n parity-check matrix H, the checksum (CS) computation of a length-n noisy codeword r is determined by first computing:

$$SYND = {rH}^{T} .$$

Herein, the T subscript represents the transpose operation, and the checksum (CS) is the number of ones in SYND.

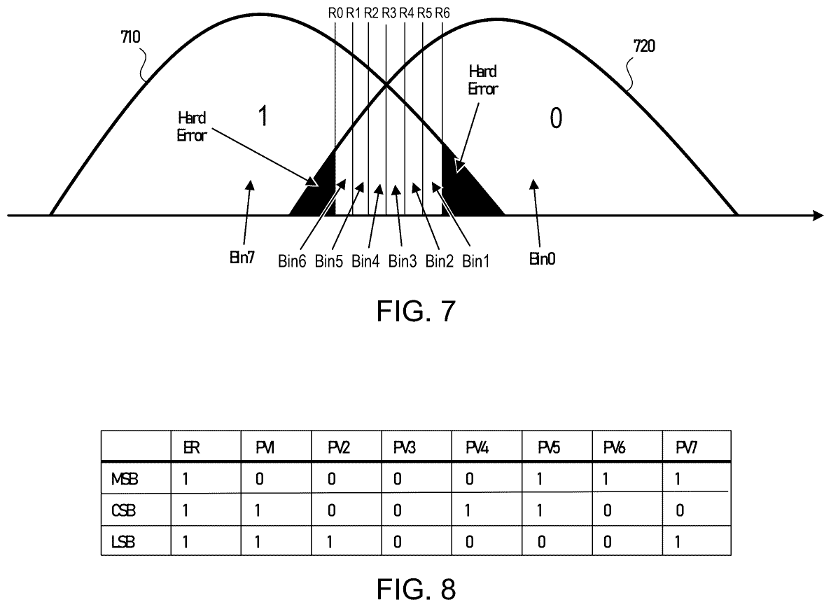

In some embodiments, the soft read channels of a single-level cell (SLC) NAND, which are illustrated in FIG. 7, are considered. As shown therein, the seven read channels {R0, R1, . . . , R6} divide the entire voltage range into eight bins, labeled Bin0, Bin1, . . . , Bin7. The curves 710 and 720 in FIG. 7 represent the probability density functions (PDFs) of the actual voltage distribution of the corresponding written voltage.

As shown in FIG. 7, the left curve 710 corresponds to written value 1, the right curve 720 corresponds to written value 0, and the probability of writing a value 0 and a value 1 are assumed to be the same. The 7 thresholds divide the area under curves into eight parts, namely Bin0, Bin1, Bin2, Bin3, . . . , Bin7. The notation y=Bin0, Bin1, . . . , Bin7 (or simply y=0, 1, 2, . . . , 7) is used to represent the event where the read result falls into the respective bin, e.g., Biny; this representation is referred to as a bin label. Furthermore, x=0 and x=1 is used to represent the originally stored information as being a 0 or 1, respectively, and corresponding to the left PDF and right PDF. Accordingly, the log-likelihood ratio (LLR) of Bin i (with i=0, . . . , 7) is defined as:

$$LLR ( i ) = log ( \frac{p ( y - i \vert x = 0 )}{p ( y - i \vert x = 1 )} ) .$$

In the above-described framework, hard errors are defined as cell bits that fall out of the soft range with wrong sign. In FIG. 7, the area corresponding to a hard error is the union of the two regions labeled “Hard Error” and, as also shown in FIG. 1, the incorrect bits that fall in Bin0 and Bin7 are defined as hard errors. Consequently, both Bin0 and Bin7 are referred to as hard error bins.

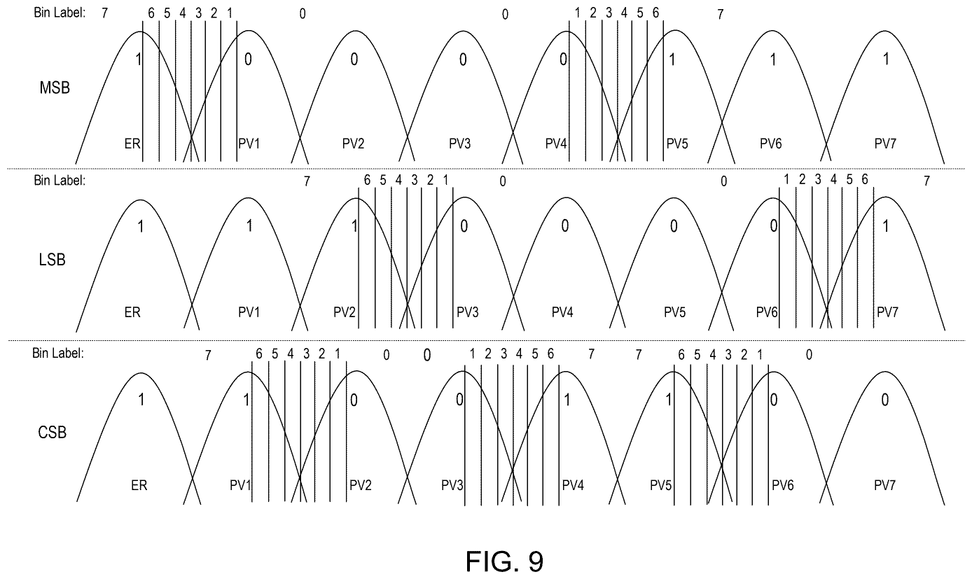

In some embodiments, the soft read channels of a triple-level cell (TLC) NAND are considered. The TLC NAND has eight states, denoted ER, PV1, PV2, . . . , PV7. An example of the gray labeling for the TLC NAND is shown in FIG. 8, and the corresponding seven reads and bin labels of each page (e.g., most significant bit (MSB), central significant bit (CSB), and least significant bit (LSB)) are shown in FIG. 9. For each set of bin labels in each of the pages shown in FIG. 9, the incorrect bits in Bin0 and Bin7 are categorized as hard errors, and consequently, both Bin0 and Bin7 are referred to as hard error bins.

For both SLC NAND and TLC NAND devices, hard errors in Bin0 and Bin7 have the most significant impact on soft correction capability compared to errors in other bins. To achieve optimal soft correction capability, optimal LLRs should be configured for hard error bins Bin0 and Bin7. However, optimal LLRs cannot be configured at the outset of a soft decoding process because not enough information related to the hard error bins is available. Embodiments of the disclosed technology are configured to selectively count the errors in the hard error bins during the soft decoding process to progressively estimate the corresponding optimal LLRs.

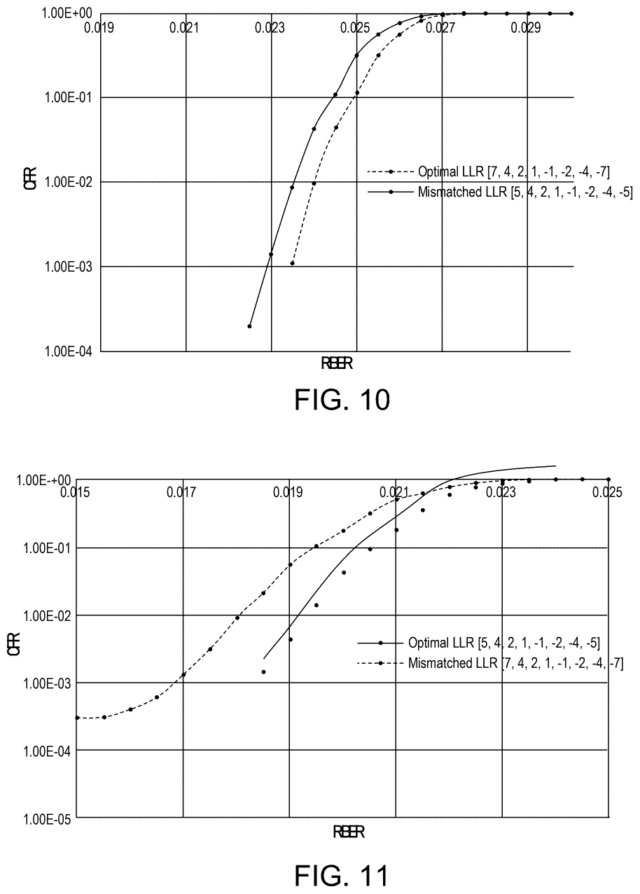

As previously discussed, using mismatched LLRs on hard error bins Bin0 and Bin7 results in significant degradation in the soft correction capability of the LDPC decoder. The two examples of mismatched LLRs that are considered, for the soft read channel of the SLC NAND shown in FIG. 1, include:
the optimal LLRs for Bin0, Bin1, Bin2, . . . Bin7 being [7, 4, 2, 1, −1, −2, −4, −7], but the mismatched LLRs used for soft decoding are [5, 4, 2, 1, −1, −2, −4, −5]. In this case, the soft correction capability loss is observed in the waterfall region, as shown in FIG. 10, which plots the codeword failure rate (CFR) as a function of the raw bit error rate (RBER).
the optimal LLRs for Bin0, Bin1, Bin2, . . . Bin7 being [5, 4, 2, 1, −1, −2, −4, −5], but the mismatched LLRs used for soft decoding are [7, 4, 2, 1, −1, −2, −4, −7]. In this case, the soft correction capability loss is observed in both the waterfall and the error floor regions, as shown in FIG. 11, which plots the CFR as a function of the RBER.

Embodiments of the disclosed technology use the following two features to combat the degradation in soft correction capability due to hard errors.

(1) LLR initialization with reduced magnitudes on the hard error bins. Prior to the soft LDPC decoding process starting, medium magnitude LLRs are used to initialize the LLRs for the hard error bins. In the examples of the SLC NAND and any page of the TLC NAND, the LLRs on Bin0 and Bin7 are configured to be close in value to the LLRs on Bin1 and Bin6. For example, instead of using LLRs [7, 4, 2, 1, −1, −2, −4, −7] for Bin0, Bin1, Bin2, . . . , Bin7, the LLRs [5, 4, 2, 1, −1, −2, −4, −5] are used for Bin0, Bin1, Bin2, . . . , Bin7 instead.

In some embodiments, and more generally, if N soft read channels are used to divide the voltage range into M=N+1 bins, and K bits are used to express each LLR (e.g., K=4 for the two examples discussed above where the LLR spans the range −7 to 7), then the magnitude of the initial LLR for the first bin (Bin0) of the M bins and the last bin (Bin(M−1)) of the M bins is less than 2^{K-1}−1. In some examples, when a medium magnitude LLR is used for the hard error bins, the magnitude of the LLR could be configured to approximately 2^{K-2}.

(2) LLR estimation of hard error bins based on selective error count. Although the initial LLRs with medium magnitudes can mitigate the error floor, when the actual optimal LLRs have a larger magnitude, a degradation in the soft correction capability in the waterfall region is observed. To alleviate the degradation in the waterfall region, and after an initial number of soft decoding iterations, the LLRs of the hard error bins (e.g., Bin0 and Bin7) are estimated and updated based on counting, in the example of the SLC NAND, the number of decoded “0” bits and the number of decoded “1” bits that fall in Bin0 and Bin7, respectively.

In the example of the SLC NAND or any page of the TLC NAND that includes 7 soft read channels and 8 bins, it is assumed that s=(s₀, s₁, . . . , sₙ₋₁) is a received bin label sequence of length n, each element of s belonging to the set (0, 1, 2, 3, 4, 5, 6, 7), where 0 means Bin0, 1 means Bin1, . . . , and d represents decoded binary sequence d=(d₀, d₁, . . . , dₙ₋₁) corresponding to the iteration that is used for LLR estimation of the hard error bins. Then, the counters B_00, B_10, B_07 and B_17 (for i=0, . . . , n−1) are computed as follows:
B_00 is the number of positions in sequences d and s such that dᵢ=0 and sᵢ=0
B_10 is the number of positions in sequences d and s such that dᵢ=1 and sᵢ=0
B_07 is the number of positions in sequences d and s such that dᵢ=0 and sᵢ=7
B_17 is the number of positions in sequences d and s such that dᵢ=1 and sᵢ=7

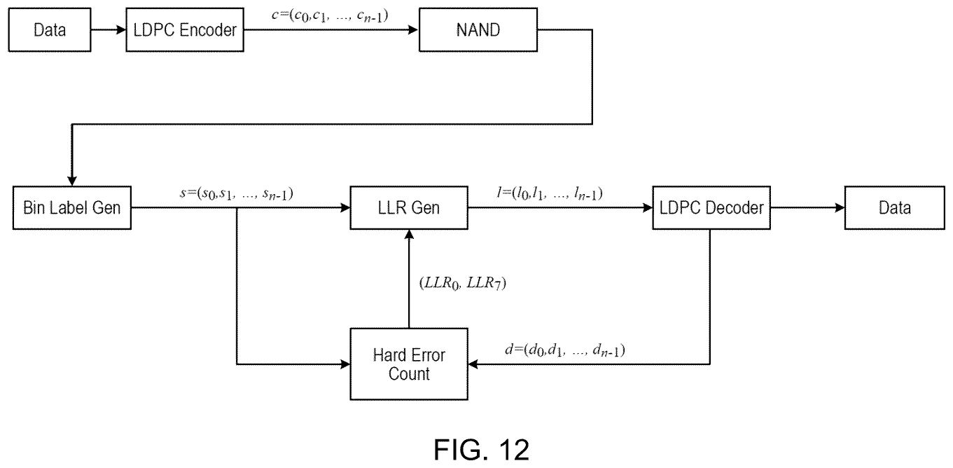

FIG. 12 is a block diagram illustrating an example architecture for improving soft decoding in a memory device based on selective error counts. In some embodiments, an example method for improving soft LDPC decoding using the example architecture shown in FIG. 12 includes the following steps:
Step 1. Receive a bin label sequence of length n from 7 reads of NAND, e.g., s=(s₀, s₁, . . . , sₙ₋₁) where each element belongs to the set (0, 1, 2, 3, 4, 5, 6, 7).
Step 2. Initialize LLR_vec=[5, 4, 2, 1, −1, −2, −4, −5] for Bin0, Bin1, Bin2, . . . Bin7. It is noted the medium magnitude of 5 for Bin0 and Bin7 is an example, and that more generally, Bin0 and Bin1 (and Bin6 and Bin7) are assigned relatively close values.
Step 3. Generate a channel LLR sequence l=(l₀, l₁, . . . , lₙ₋₁) by applying LLR_vec to the bin label sequence s as follows:

for i = 0 : n-1
l_i = LLR_vec[s_i]
end

Step 4. Iteration loop till maximum number of iterations
   a. Perform LDPC min-sum soft decoding with LLR sequence l=(l₀, l₁, . . . , lₙ₋₁) to generate a decoded sequence d=(d₀, d₁, . . . , dₙ₋₁).
   b. Calculate a checksum (CS) using the bit sequence (d₀, d₁, . . . , dₙ₋₁). If CS==0, terminate decoding since correct transmitted codeword has been determined.
   c. If (CS<α) and (iter_idx >β)
      Calculate counters B_00, B_07, B_10 and B_17
      Generate LLR0 and LLR7
      Update the LLR sequence l=(l₀, l₁, . . . , lₙ₋₁) by applying LLR0 and LLR7 to the bin label sequence s as follows:

```
        for i = 0 : n-1
            if s_i == 0, then l_i = LLR0, end
            if s_i == 7, then l_i = LLR7, end
        end
    END (if conditions)
END (iteration loop)
```

In Step 4c above, the counters are calculated (for i=0, . . . , n−1) as follows:
B_00 is the number of positions in sequences d and s such that dᵢ=0 and sᵢ=0
B_07 is the number of positions in sequences d and s such that dᵢ=0 and sᵢ=7
B_10 is the number of positions in sequences d and s such that dᵢ=1 and sᵢ=0
B_17 is the number of positions in sequences d and s such that dᵢ=1 and sᵢ=7

In Step 4c above, LLR0 and LLR7 are generated as follows:

$$LLR 0 = round ( log ( \frac{B\_ 00}{B\_ 10} ) ) and LLR 7 = round ( log ( \frac{B\_ 07}{B\_ 17} ) ) .$$

Herein, round(·) is a function returning a closest integer to an input argument and log(·) is a function returning a natural logarithm of the input argument.

In some embodiments, the thresholds α and β are predetermined thresholds that are optimized offline. In some examples, α=1500 and β=3.

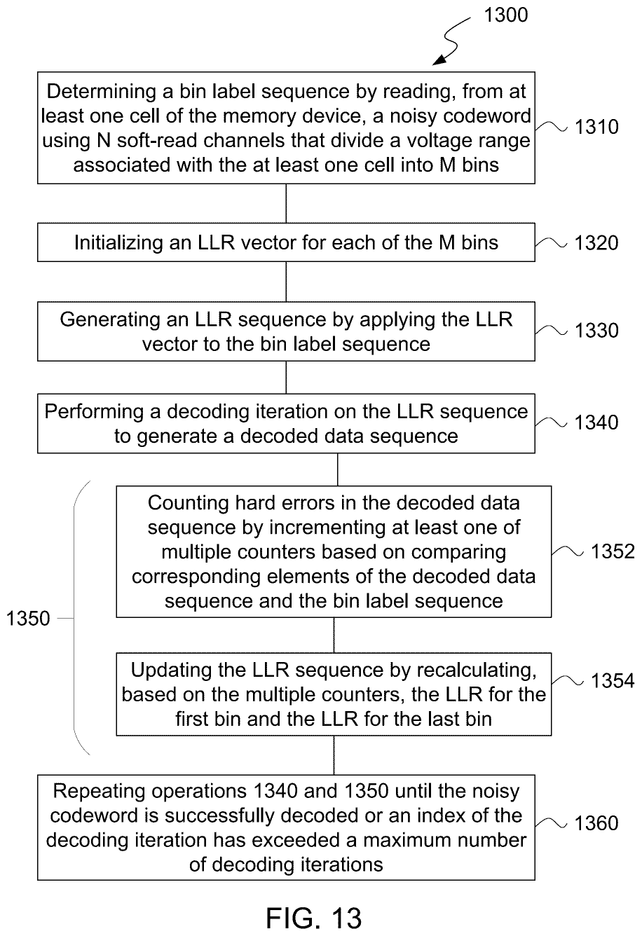

FIG. 13 show a flowchart of an example method 1300 for improving a performance of an iterative decoder in a non-volatile memory device. The method 1300 includes, at operation 1310, determining a bin label sequence by reading, from at least one cell of the memory device, a noisy codeword using N soft-read channels that divide a voltage range associated with the at least one cell into M bins. In this example, a bin label of the bin label sequence is an index of a bin of the M bins that corresponds to reading a respective bit of the noisy codeword using the N soft-read channels, and where N and M=N+1 are positive integers.

The method 1300 includes, at operation 1320, initializing a log-likelihood ratio (LLR) vector for each of the M bins. Herein, each LLR of the LLR vector is represented using K bits, a magnitude of an LLR for a first bin of the M bins and a last bin of the M bins is less than 2^{K-1}−1, and K is a positive integer. With reference to FIG. 7, the first bin and the last bin of the M bins correspond to the hard error bins.

The method 1300 includes, at operation 1330, generating an LLR sequence by applying the LLR vector to the bin label sequence, and at operation 1340, performing a decoding iteration on the LLR sequence to generate a decoded data sequence.

The method 1300 includes, at operation 1350, performing operations 1352 and 1354 upon determining that a condition, indicative of the noisy codeword not being successfully decoded, is satisfied. In some embodiments, the condition being satisfied comprises a checksum of the decoded data sequence being less than a first threshold.

The method 1300 includes, at operation 1352, counting hard errors in the decoded data sequence by incrementing at least one of multiple counters based on comparing corresponding elements of the decoded data sequence and the bin label sequence.

The method 1300 includes, at operation 1354, updating the LLR sequence by recalculating, based on the multiple counters, the LLR for the first bin and the LLR for the last bin, e.g., the hard error bins.

The method 1300 includes, at operation 1360, repeating operations 1340 and 1350 until the noisy codeword is successfully decoded or an index of the decoding iteration has exceeded a maximum number of decoding iterations.

In some embodiments, the condition being satisfied further comprises the index of the decoding iteration being greater than a second threshold.

In some embodiments, the multiple counters comprise a first counter (B_00), a second counter (B_10), a third counter (B_0(M−1)), and a fourth counter (B_1(M−1)). Herein, the first counter (B_00) is incremented by one when the corresponding elements of the decoded data sequence and the bin label sequence are both zero, the second counter (B_10) is incremented by one when the corresponding elements of the decoded data sequence and the bin label sequence are one and zero, respectively, the third counter (B_0(M−1)) is incremented by one when the corresponding elements of the decoded data sequence and the bin label sequence are zero and (M−1), respectively, and the fourth counter (B_1(M−1)) is incremented by one when the corresponding elements of the decoded data sequence and the bin label sequence are one and (M−1), respectively.

In some embodiments, the method 1300 further includes the operations of computing the LLR for the first bin (LLR_0) as round(log(B_00/B_10)), computing the LLR for the last bin (LLR_(M−1)) as round(log(B_0(M−1)/B_1(M−1))), and replacing the LLR for the first bin and the last bin with LLR_0 and LLR_(M−1), respectively. Herein, round(·) is a function returning a closest integer to an input argument and log(·) is a function returning a natural logarithm of the input argument.

In some embodiments, the magnitude of the LLR for the first bin is greater than the magnitude of the LLR for a second bin by a fixed value, and wherein the magnitude of the LLR for the last bin is greater than the magnitude of the LLR for a second to last bin by the fixed value. In some examples, the fixed value is one.

In some embodiments, the iterative decoder comprises a low-density parity-check (LDPC) decoder and the decoding iteration comprises a min-sum soft decoding iteration.

In some embodiments, the method 1300 further includes the operation of determining the checksum based on computing a syndrome of the decoded data sequence.

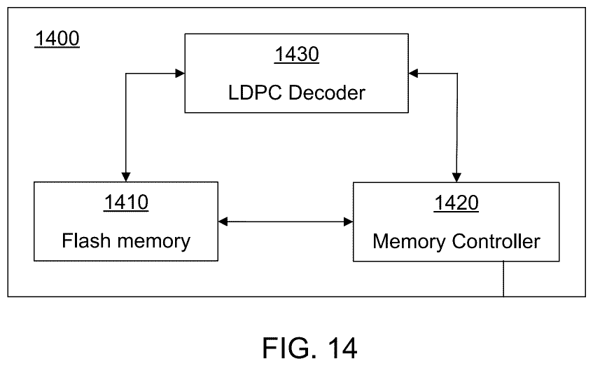

FIG. 14 is an example diagram illustrating a storage device that can be configured to implement the described embodiments. Referring to FIG. 14, a data storage device 1400 may include a flash memory 1410, a memory controller 1420, and an LDPC decoder 1430. The memory controller 1420 may control the flash memory 1410 and the LDPC decoder 1430 in response to control signals input from the outside of the data storage device 1400. In the data storage device 1400, the flash memory 1410 may be configured the same or substantially the same as a nonvolatile memory device. That is, the flash memory 1410 may read data from selected memory cells using different read voltages to output it to the memory controller 1420.

In some embodiments, the data storage device 1400 may be a memory card device, an SSD device, a multimedia card device, an SD card, a memory stick device, an HDD device, a hybrid drive device, or an USB flash device. For example, the data storage device 1400 may be a card which satisfies the standard for user devices such as a digital camera, a personal computer, and so on.

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, i.e., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. Processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A method for improving a performance of an iterative decoder in a memory device, comprising:
(a) determining a bin label sequence by reading, from at least one cell of the memory device, a noisy codeword using N soft-read channels that divide a voltage range associated with the at least one cell into M bins, wherein a bin label of the bin label sequence is an index of a bin of the M bins that corresponds to reading a respective bit of the noisy codeword using the N soft-read channels, and wherein N and M=N+1 are positive integers;
(b) initializing a log-likelihood ratio (LLR) vector for each of the M bins, wherein each LLR of the LLR vector is represented using K bits, wherein a magnitude of an LLR for a first bin of the M bins and a last bin of the M bins is less than 2^{K-1}−1, and wherein K is a positive integer;
(c) generating an LLR sequence by applying the LLR vector to the bin label sequence;
(d) performing a decoding iteration on the LLR sequence to generate a decoded data sequence;
upon determining that a condition, indicative of the noisy codeword not being successfully decoded, is satisfied,
(e) counting hard errors in the decoded data sequence by incrementing at least one of multiple counters based on comparing corresponding elements of the decoded data sequence and the bin label sequence; and
(f) updating the LLR sequence by recalculating, based on the multiple counters, the LLR for the first bin and the LLR for the last bin; and
(g) repeating operations (d) through (f) until the noisy codeword is successfully decoded or an index of the decoding iteration has exceeded a maximum number of decoding iterations,
wherein the condition being satisfied comprises a checksum of the decoded data sequence being less than a first threshold.

2. The method of claim 1, wherein the condition being satisfied further comprises the index of the decoding iteration being greater than a second threshold.

3. The method of claim 1, wherein the multiple counters comprise a first counter (B_00), a second counter (B_10), a third counter (B_0(M−1)), and a fourth counter (B_1(M−1)).

4. The method of claim 3, wherein:
the first counter (B_00) is incremented by one when the corresponding elements of the decoded data sequence and the bin label sequence are both zero,
the second counter (B_10) is incremented by one when the corresponding elements of the decoded data sequence and the bin label sequence are one and zero, respectively,
the third counter (B_0(M−1)) is incremented by one when the corresponding elements of the decoded data sequence and the bin label sequence are zero and (M−1), respectively, and
the fourth counter (B_1(M−1)) is incremented by one when the corresponding elements of the decoded data sequence and the bin label sequence are one and (M−1), respectively.

5. The method of claim 4, wherein updating the LLR sequence comprises:
computing the LLR for the first bin (LLR_0) as round(log(B_00/B_10));
computing the LLR for the last bin (LLR_(M−1)) as round(log(B_0(M−1)/B_1(M−1)));
replacing the LLR for the first bin and the last bin with LLR_0 and LLR_(M−1), respectively, wherein round(·) is a function returning a closest integer to an input argument and log(·) is a function returning a natural logarithm of the input argument.

6. The method of claim 1, wherein the magnitude of the LLR for the first bin is greater than the magnitude of the LLR for a second bin by a fixed value, and wherein the magnitude of the LLR for the last bin is greater than the magnitude of the LLR for a second to last bin by the fixed value.

7. The method of claim 6, wherein the fixed value is one.

8. The method of claim 1, wherein the iterative decoder comprises a low-density parity-check (LDPC) decoder and the decoding iteration comprises a min-sum soft decoding iteration.

9. The method of claim 1, further comprising:
determining the checksum based on computing a syndrome of the decoded data sequence.

10. A system for improving a performance of an iterative decoder in a memory device, comprising:
a processor and a memory including instructions stored thereupon, wherein the instructions upon execution by the processor cause the processor to:
(a) determine a bin label sequence by reading, from at least one cell of the memory device, a noisy codeword using N soft-read channels that divide a voltage range associated with the at least one cell into M bins, wherein a bin label of the bin label sequence is an index of a bin of the M bins that corresponds to reading a respective bit of the noisy codeword using the N soft-read channels, and wherein N and M=N+1 are positive integers;
(b) initialize a log-likelihood ratio (LLR) vector for each of the M bins, wherein each LLR of the LLR vector is represented using K bits, wherein a magnitude of an LLR for a first bin of the M bins and a last bin of the M bins is less than 2^{K-1}−1, and wherein K is a positive integer;
(c) generate an LLR sequence by applying the LLR vector to the bin label sequence;
(d) perform a decoding iteration on the LLR sequence to generate a decoded data sequence;
upon determining that a condition, indicative of the noisy codeword not being successfully decoded, is satisfied,
(e) count hard errors in the decoded data sequence by incrementing at least one of multiple counters based on comparing corresponding elements of the decoded data sequence and the bin label sequence; and
(f) update the LLR sequence by recalculating, based on the multiple counters, the LLR for the first bin and the LLR for the last bin; and
(g) repeat operations (d) through (f) until the noisy codeword is successfully decoded or an index of the decoding iteration has exceeded a maximum number of decoding iterations,
wherein the condition being satisfied comprises a checksum of the decoded data sequence being less than a first threshold.

11. The system of claim 10, wherein the condition being satisfied further comprises the index of the decoding iteration being greater than a second threshold.

12. The system of claim 10, wherein the multiple counters comprise a first counter (B_00), a second counter (B_10), a third counter (B_0(M−1)), and a fourth counter (B_1(M−1)).

13. The system of claim 12, wherein:
the first counter (B_00) is incremented by one when the corresponding elements of the decoded data sequence and the bin label sequence are both zero,
the second counter (B_10) is incremented by one when the corresponding elements of the decoded data sequence and the bin label sequence are one and zero, respectively,
the third counter (B_0(M−1)) is incremented by one when the corresponding elements of the decoded data sequence and the bin label sequence are zero and (M−1), respectively, and
the fourth counter (B_1(M−1)) is incremented by one when the corresponding elements of the decoded data sequence and the bin label sequence are one and (M−1), respectively.

14. The system of claim 13, wherein the instructions upon execution by the processor cause the processor to:
computing the LLR for the first bin (LLR_0) as round(log(B_00/B_10));
computing the LLR for the last bin (LLR_(M−1)) as round(log(B_0(M−1)/B_1(M−1)));
replacing the LLR for the first bin and the last bin with LLR_0 and LLR_(M−1), respectively, wherein round(·) is a function returning a closest integer to an input argument and log(·) is a function returning a natural logarithm of the input argument.

15. The system of claim 10, wherein the magnitude of the LLR for the first bin is greater than the magnitude of the LLR for a second bin by a fixed value, and wherein the magnitude of the LLR for the last bin is greater than the magnitude of the LLR for a second to last bin by the fixed value.

16. A non-transitory computer-readable storage medium having instructions stored thereupon for improving a performance of a decoder in a memory device, comprising:
(a) instructions for determining a bin label sequence by reading, from at least one cell of the memory device, a noisy codeword using N soft-read channels that divide a voltage range associated with the at least one cell into M bins, wherein a bin label of the bin label sequence is an index of a bin of the M bins that corresponds to reading a respective bit of the noisy codeword using the N soft-read channels, and wherein N and M=N+1 are positive integers;
(b) instructions for initializing a log-likelihood ratio (LLR) vector for each of the M bins, wherein each LLR of the LLR vector is represented using K bits, wherein a magnitude of an LLR for a first bin of the M bins and a last bin of the M bins is less than 2^{K-1}−1, and wherein K is a positive integer;
(c) instructions for generating an LLR sequence by applying the LLR vector to the bin label sequence;
(d) instructions for performing a decoding iteration on the LLR sequence to generate a decoded data sequence;
in response to instructions for determining that a condition, indicative of the noisy codeword not being successfully decoded, is satisfied,
(e) instructions for counting hard errors in the decoded data sequence by incrementing at least one of multiple counters based on comparing corresponding elements of the decoded data sequence and the bin label sequence; and
(f) instructions for updating the LLR sequence by recalculating, based on the multiple counters, the LLR for the first bin and the LLR for the last bin; and
(g) instructions for repeating operations (d) through (f) until the noisy codeword is successfully decoded or an index of the decoding iteration has exceeded a maximum number of decoding iterations,
wherein the condition being satisfied comprises a checksum of the decoded data sequence being less than a first threshold.

17. The non-transitory computer-readable storage medium of claim 16, wherein the condition being satisfied further comprises the index of the decoding iteration being greater than a second threshold.

18. The non-transitory computer-readable storage medium of claim 16, wherein the multiple counters comprise a first counter (B_00), a second counter (B_10), a third counter (B_0(M−1)), and a fourth counter (B_1(M−1)).

19. The non-transitory computer-readable storage medium of claim 18, wherein:
the first counter (B_00) is incremented by one when the corresponding elements of the decoded data sequence and the bin label sequence are both zero,
the second counter (B_10) is incremented by one when the corresponding elements of the decoded data sequence and the bin label sequence are one and zero, respectively,
the third counter (B_0(M−1)) is incremented by one when the corresponding elements of the decoded data sequence and the bin label sequence are zero and (M−1), respectively, and
the fourth counter (B_1(M−1)) is incremented by one when the corresponding elements of the decoded data sequence and the bin label sequence are one and (M−1), respectively.

20. The non-transitory computer-readable storage medium of claim 16, wherein the magnitude of the LLR for the first bin is greater than the magnitude of the LLR for a second bin by a fixed value, and wherein the magnitude of the LLR for the last bin is greater than the magnitude of the LLR for a second to last bin by the fixed value.
